(19) United States
(12) Patent Application Publication
(10) Pub. No.: US 2024/0203781 A1
(43) Pub. Date: Jun. 20, 2024

(54) CHUCK TABLE

(71) Applicant: DISCO CORPORATION, Tokyo (JP)

(72) Inventor: Kazuki INOMATA, Tokyo (JP)

(21) Appl. No.: 18/517,530

(22) Filed: Nov. 22, 2023

(30) Foreign Application Priority Data
Dec. 15, 2022 (JP) 2022-200182

(51) Int. Cl. H01L 21/683; B23K 37/04

(52) U.S. Cl. CPC H01L 21/6838; B23K 37/04; B23K 26/38

(57) ABSTRACT

A chuck table for holding a workpiece under suction thereon includes a plate-shaped porous plate having a holding surface for holding the workpiece under suction thereon and a plate-shaped base having an upper surface on which the porous plate is placed, the upper surface being held in contact with a lower surface of the porous plate, the lower surface being positioned opposite the holding surface. The base has a plurality of suction channels defined therein that are exposed on the upper surface of the base and that are for transmitting a negative pressure from a suction source to the porous plate. The base is configurable so that the ratio of the area of the suction channels being exposed and able to supply the negative pressure to the porous plate is smaller in a central portion of the upper surface than in an outer circumferential portion of the upper surface.

### BACKGROUND OF THE INVENTION

### Field of the Invention

The present invention relates to a chuck table for holding a workpiece under suction thereon.

### Description of the Related Art

Chuck tables are used to support workpieces such as semiconductor wafers when the workpieces are processed by cutting, laser processing, etc. A chuck table has a holding surface for holding a workpiece under suction thereon. Usually, the workpiece as it is supported on the holding surface is held under suction on the holding surface. Chuck tables incorporated in a cutting apparatus and a laser processing apparatus have a circular base made of a metal material such as stainless steel. The base has a circular cavity defined in an upper surface thereof. The cavity is smaller in diameter than the base. A circular porous plate that is made of porous ceramic is fitted in the cavity and usually secured to the base by an adhesive. The circular porous plate in the cavity has an upper surface exposed upwardly.

The bottom of the cavity in the base has a plurality of annular suction channels concentrically defined therein. The annular suction channels are spaced at substantially equal intervals diametrically across the cavity. The bottom of the cavity also has a plurality of straight suction channels defined therein diametrically across the base. The straight suction channels interconnect the annular suction channels. A hollow cylindrical suction channel that is fluidly connected to a suction source such as a vacuum pump is defined centrally in the bottom of the cavity. The hollow cylindrical suction channel is held in fluid communication with the annular suction channels via the straight suction channels. A negative pressure generated by the suction source is transmitted through all the suction channels to the upper surface of the porous plate. The upper surface of the porous plate and the upper surface of the base that surrounds the cavity jointly function as the holding surface for holding the workpiece under suction thereon (see, for example, JP 2014-143295A).

The chuck table described above tends to apply a stronger suction force to a radially central portion of the porous plate than to a radially outer circumferential portion of the porous plate. Since the porous plate and the workpiece placed thereon are likely to be deformed near a radially central portion of the chuck table, the upper surface of the workpiece is likely to have different heights or vertical positions. The different heights or vertical positions of the upper surface of the workpiece may cause the workpiece to suffer a processing failure. Further, the workpiece held under suction on the chuck table may possibly yield to deformations and be damaged.

### SUMMARY OF THE INVENTION

It is therefore an object of the present invention to provide a chuck table that reduces the difference between suction forces applied to a radially central portion and a radially outer circumferential portion of a holding surface thereof.

In accordance with an aspect of the present invention, there is provided a chuck table for holding a workpiece under suction thereon. The chuck table includes a plate-shaped porous plate having a holding surface for holding the workpiece under suction thereon, and a plate-shaped base having an upper surface on which the porous plate is placed, the upper surface being held in contact with a lower surface of the porous plate, the lower surface being positioned opposite the holding surface. The base has a plurality of suction channels defined therein that are exposed on the upper surface of the base and that are for transmitting a negative pressure from a suction source to the porous plate. When the base is viewed in plan, the base is configurable so that the ratio of the area of the suction channels that are exposed in such a manner as to be able to supply the negative pressure to the porous plate to the sum of the area of the upper surface of the base and the area of the suction channels that are exposed in such a manner as to be able to supply the negative pressure to the porous plate is smaller in a central portion of the upper surface of the base than in an outer circumferential portion of the upper surface of the base.

Preferably, when the base is viewed in plan, the ratio of the area of the suction channels to the sum of the area of the upper surface of the base and the area of the suction channels is smaller in the central portion of the upper surface of the base than in the outer circumferential portion of the upper surface of the base.

Preferably, the suction channels that are exposed in such a manner as to be able to supply the negative pressure to the porous plate include a hollow cylindrical suction channel that is defined diametrically centrally in the base and that extends axially through the base from the upper surface thereof to a lower surface of the base along a thicknesswise direction of the base, and a plurality of annular suction channels defined in the base concentrically around the hollow cylindrical suction channel, the base further includes a plurality of lower suction channels that are defined therein beneath the annular suction channels and that extend radially in the base when the base is viewed in plan, with the negative pressure being transmittable from the suction source through the hollow cylindrical suction channel to the lower suction channels, each of the annular suction channels includes a plurality of fluid communication channels fluidly connected to the lower suction channels along the thicknesswise direction of the base, and at least either all the fluid communication channels in each of one or more of the annular suction channels that are positioned in the central portion of the upper surface of the base or the hollow cylindrical suction channel is sealed, and when the base is viewed in plan, the ratio of the area of the suction channels that are exposed in such a manner as to be able to supply the negative pressure to the porous plate to the sum of the area of the upper surface of the base and the area of the suction channels that are exposed in such a manner as to be able to supply the negative pressure to the porous plate is smaller in the central portion of the upper surface of the base than in the outer circumferential portion of the upper surface of the base.

With the chuck table according to the aspect of the present invention, when the base is viewed in plan, the base is configurable so that the ratio of the area of the suction channels that are exposed in such a manner as to be able to supply the negative pressure to the porous plate to the sum of the area of the upper surface of the base and the area of the suction channels that are exposed in such a manner as to be able to supply the negative pressure to the porous plate is smaller in a central portion of the upper surface of the base than in an outer circumferential portion of the upper surface of the base. Therefore, the difference between suction forces applied to the central portion and the outer circumferential portion of the holding surface is reduced. Further, the workpiece that is held under suction on the holding surface is prevented from being damaged due to deformations which would otherwise be caused by different suction forces applied to the holding surface.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is an exploded perspective view of a circular chuck table according to a first embodiment of the present invention;

FIG. 2A is a cross-sectional view taken along line A-A of FIG. 1;

FIG. 2B is a cross-sectional view taken along line B-B of FIG. 1;

FIG. 3A is a plan view of a base of the chuck table according to the first embodiment;

FIG. 3B is a view illustrating the results of an experiment conducted to measure deformations of a workpiece held under suction on a holding surface of the chuck table according to the first embodiment;

FIG. 4A is a plan view of a base of a chuck table according to a comparative example;

FIG. 4B is a view illustrating the results of an experiment conducted to measure deformations of a workpiece held under suction on a holding surface of the chuck table according to the comparative example;

FIG. 5 is an exploded perspective view of a circular chuck table according to a second embodiment of the present invention;

FIG. 6 is a perspective view illustrating a plurality of downward suction channels defined in a base of the chuck table according to the second embodiment;

FIG. 7A is a cross-sectional view taken along line C-C of FIG. 6;

FIG. 7B is a cross-sectional view taken along line D-D of FIG. 6;

FIG. 7C is a cross-sectional view taken along line D-D of FIG. 6, illustrating the manner in which a communication passage is sealed by a sealing member; and

FIG. 8 is a perspective view of a laser processing apparatus that incorporates the chuck table according to the first or second embodiment.

### DETAILED DESCRIPTION OF THE PREFERRED EMBODIMENTS

### First Embodiment

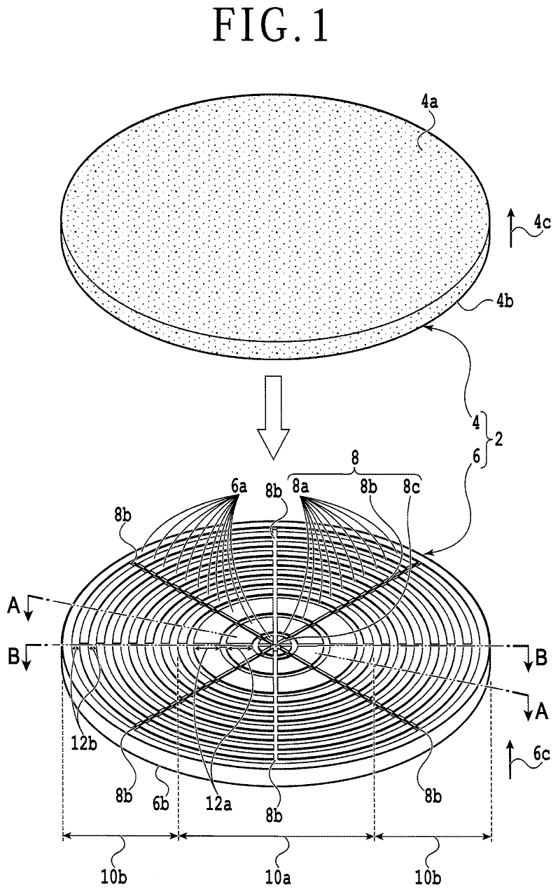

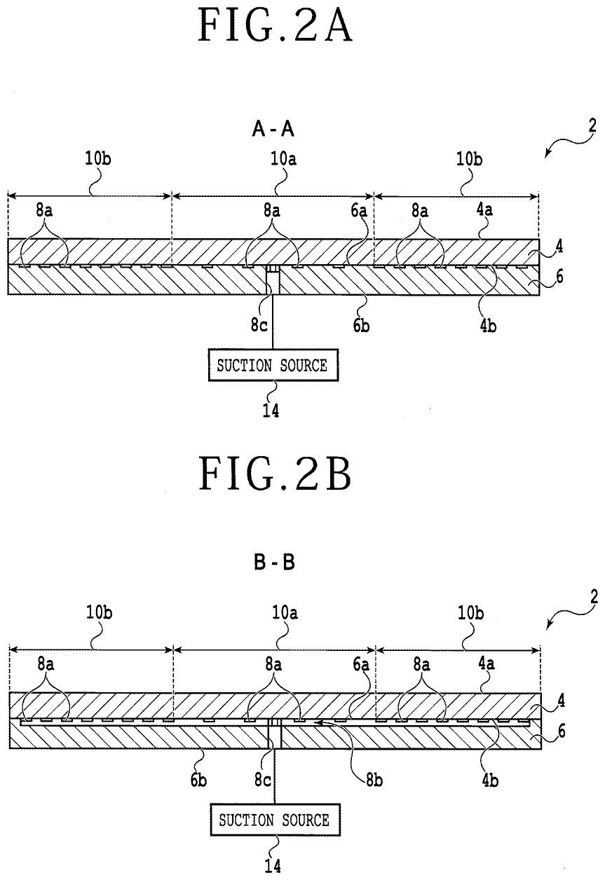

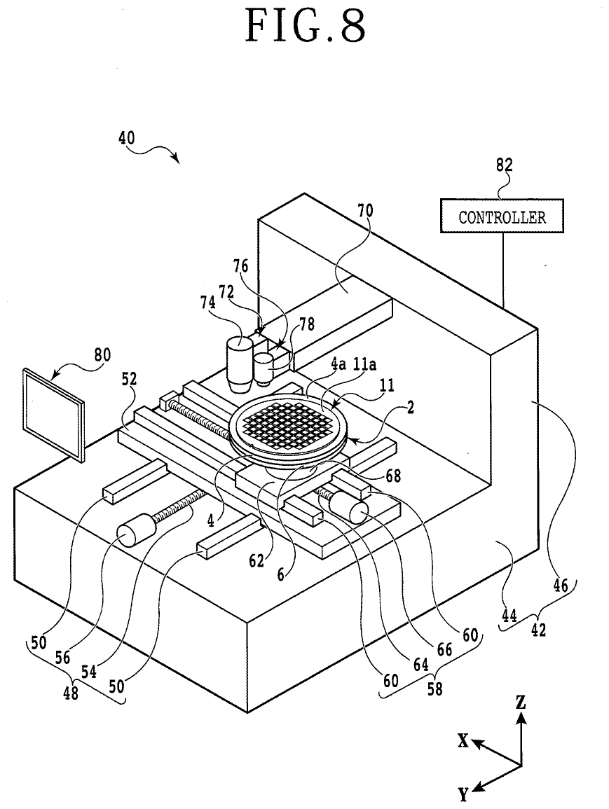

A first embodiment of the present invention will be described in detail below with reference to FIGS. 1 through 4B. First, a chuck table 2 according to the first embodiment will be described below with reference to FIGS. 1, 2A, and 2B. FIG. 1 illustrates in exploded perspective the chuck table 2 that is circular in shape according to the first embodiment. FIG. 2A is a cross-sectional view taken along line A-A of FIG. 1, and FIG. 2B is a cross-sectional view taken along line B-B of FIG. 1. The chuck table 2 is used to hold a workpiece 11 (see FIG. 8) thereon under a negative pressure.

The chuck table 2 has a porous plate 4 shaped as a circular plate. The porous plate 4 is made of a porous material such as porous ceramic or porous glass. The porous plate 4 includes a multiplicity of pores that are joined together in a mesh-like configuration. The porous plate 4 has an upper surface that is exposed upwardly as illustrated in FIG. 1 and to which a negative pressure is applied from a suction source 14 (see FIGS. 2A and 2B) such as a vacuum pump through the pores. The upper surface of the porous plate 4 functions as a holding surface 4a for holding the workpiece 11 under suction thereon. As illustrated in FIG. 1, the holding surface 4a is a substantially flat circular surface.

The porous plate 4 has a lower surface 4b that lies opposite the holding surface 4a along a thicknesswise direction 4c of the porous plate 4, the lower surface 4b being exposed downwardly. The lower surface 4b is also a substantially flat circular surface as with the holding surface 4a. The chuck table 2 further has a base 6 shaped as a circular plate that is of substantially the same diameter as that of the porous plate 4. The base 6 has an upper surface 6a on which the porous plate 4 is placed. The porous plate 4 as it is placed on the base 6 has an outer circumferential side surface exposed laterally. The upper surface 6a is a surface on an axial end of the base 6 along a thicknesswise direction 6c thereof. When the porous plate 4 is placed on the base 6, the lower surface 4b of the porous plate 4 is held in contact with the upper surface 6a of the base 6. The base 6 also has a lower surface 6b that lies opposite the upper surface 6a along the thicknesswise direction 6c of the base 6.

The porous plate 4 is held under suction on the base 6 by the negative pressure transmitted from the suction source 14 to the porous plate 4. However, the porous plate 4 may alternatively be secured to the base 6 by an adhesive or bolts. The base 6 has a plurality of annular suction channels 8a defined in the upper surface 6a and exposed upwardly. According to the first embodiment, the annular suction channels 8a have substantially the same widths. The width of one annular suction channel 8a is defined as a length of the one annular suction channel 8a in a direction diametrically across the base 6.

In a circular radially central portion 10a of the upper surface 6a of the base 6, the annular suction channels 8a are spaced at first intervals 12a that are substantially equal to each other. In an annular radially outer circumferential portion 10b of the upper surface 6a of the base 6, the outer circumferential portion 10b surrounding the circular central portion 10a, the annular suction channels 8a are spaced at second intervals 12b that are substantially equal to each other. The second intervals 12b are smaller than the first intervals 12a, e.g., are approximately ⅓ to approximately ½ of the first intervals 12a.

In addition to the different intervals between the annular suction channels 8a in the central portion 10a and the outer circumferential portion 10b, the widths of the annular suction channels 8a in the central portion 10a and the widths of the annular suction channels 8a in the outer circumferential portion 10b may be different from each other. For example, the widths of the annular suction channels 8a in the central portion 10a may be in a range of 1.5 to 2.0 times the widths of the annular suction channels 8a in the outer circumferential portion 10b.

The circular central portion 10a has a diameter of approximately 100 mm, for example, and the base 6 has a diameter of approximately 220 mm, for example. However, the diameter of the central portion 10a and the diameter of the base 6 are not limited to these numerical values, and may be adjusted to appropriate values in view of the magnitude of the negative pressure to act on the workpiece 11.

The base 6 further has a plurality of straight suction channels 8b defined in the upper surface 6a radially thereacross and exposed upwardly. The straight suction channels 8b extend radially from the diametrical center of the upper surface 6a to the annular suction channel 8a that is positioned in a radially outermost portion of the upper surface 6a.

The base 6 further has a hollow cylindrical suction channel 8c defined centrally in the upper surface 6a and exposed upwardly. The hollow cylindrical suction channel 8c is fluidly connected to the annular suction channels 8a through the straight suction channels 8b. The hollow cylindrical suction channel 8c extends axially through the base 6 from the upper surface 6a to the lower surface 6b along the thicknesswise direction 6c of the base 6.

The annular suction channels 8a, the straight suction channels 8b, and the hollow cylindrical suction channel 8c divide the upper surface 6a into a plurality of arcuate island-shaped regions. The annular suction channels 8a and the arcuate island-shaped regions of the upper surface 6a are alternately arranged radially across the base 6 as it is viewed in plan.

FIG. 2A illustrates in cross section the chuck table 2 along a cross-sectional plane that passes through the annular suction channels 8a and the hollow cylindrical suction channel 8c but does not pass through the straight suction channels 8b. FIG. 2B illustrates in cross section the chuck table 2 along a cross-sectional plane that passes through the annular suction channels 8a, one of the straight suction channels 8b, and the hollow cylindrical suction channel 8c.

The hollow cylindrical suction channel 8c is fluidly connected to the suction source 14 via an undepicted fluid channel connected to the base 6. According to the first embodiment, the annular suction channels 8a, the straight suction channels 8b, and the hollow cylindrical suction channel 8c make up a plurality of suction channels 8 in the base 6. A negative pressure generated by the suction source 14 is transmitted through the suction channels 8 to the porous plate 4. According to the first embodiment, in other words, the suction channels 8 are exposed on the upper surface 6a in such a manner as to be able to supply the negative pressure to the porous plate 4.

The outer circumferential side surface of the porous plate 4 as it is placed on the base 6 remains exposed outwardly of the base 6, i.e., is not covered with the base 6. Therefore, when a negative pressure from the suction source 14 is transmitted to the base 6, the porous plate 4 draws in a small amount of atmospheric gas, e.g., air, from the outer circumferential side surface thereof, resulting in a slight reduction in the suction force acting on the porous plate 4. However, since the reduction in the suction force is extremely low, the porous plate 4 can be held under suction on the base 6 and the workpiece 11 can be held under suction on the holding surface 4a without fail.

According to the first embodiment, the base 6 is constructed such that, when the base 6 is viewed in plan, the ratio of the area of the suction channels 8 to the sum of the area of the upper surface 6a and the area of the suction channels 8 is smaller in the central portion 10a than in the outer circumferential portion 10b.

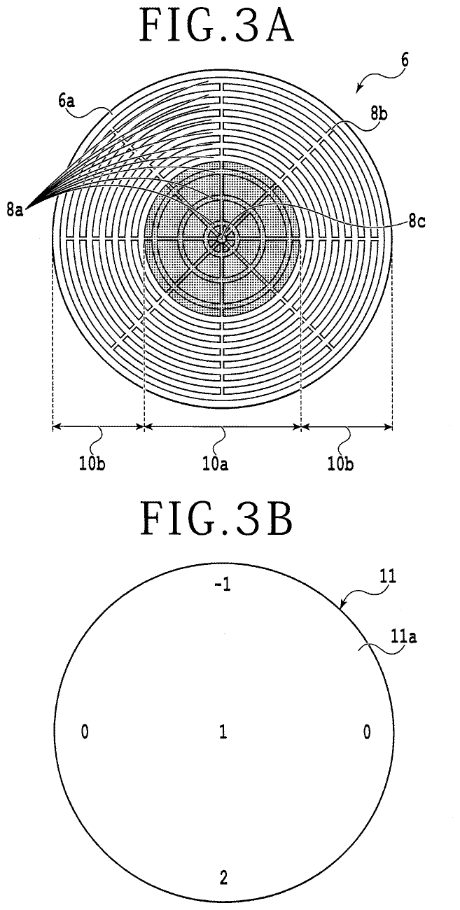

FIG. 3A illustrates in plan the base 6 according to the first embodiment. In FIG. 3A, the central portion 10a of the upper surface 6a of the base 6 is illustrated as hatched. The base 6 is constructed such that, when the base 6 is viewed in plan, the ratio (S2/(S1+S2)) of the area (S2) of all the suction channels 8 positioned in the central portion 10a to the sum of the area (S1) of the upper surface 6a positioned in the central portion 10a and the area (S2) of all the suction channels 8 positioned in the central portion 10a is smaller than the ratio (S4/(S3+S4)) of the area (S4) of all the suction channels 8 positioned in the outer circumferential portion 10b to the sum of the area (S3) of the upper surface 6a positioned in the outer circumferential portion 10b and the area (S4) of all the suction channels 8 positioned in the outer circumferential portion 10b.

In the example illustrated in FIG. 3A, the ratio (S2/(S1+S2)) of the area (S2) of all the suction channels 8 positioned in the central portion 10a to the sum of the area (S1) of the upper surface 6a positioned in the central portion 10a and the area (S2) of all the suction channels 8 positioned in the central portion 10a is approximately 27%. SN (N is a natural number) that denotes each of the areas described above is added for explanatory purposes, and is not illustrated in FIG. 3A. By contrast, the ratio (S4/(S3+S4)) of the area (S4) of all the suction channels 8 positioned in the outer circumferential portion 10b to the sum of the area (S3) of the upper surface 6a positioned in the outer circumferential portion 10b and the area (S4) of all the suction channels 8 positioned in the outer circumferential portion 10b is approximately 53%.

Therefore, when the base 6 is viewed in plan, the ratio of the area taken up by the suction channels 8 to the sum of the areas taken up by the upper surface 6a and the suction channels 8 is smaller in the central portion 10a than in the outer circumferential portion 10b. The ratio of the areas thus established is effective to reduce the difference between the magnitudes of negative pressures applied to the central portion 10a and the outer circumferential portion 10b. Therefore, when the porous plate 4 is placed on the base 6 and the workpiece 11 is held under suction on the holding surface 4a, the difference between suction forces applied to the radially central portion 10a and the radially outer circumferential portion 10b of the holding surface 4a is reduced. Further, the workpiece 11 that is held under suction on the holding surface 4a is prevented from being damaged due to deformations which would otherwise be caused by different suction forces applied to the holding surface 4a.

FIG. 3B illustrates the results of an experiment conducted to measure deformations of the workpiece 11 held under suction on the holding surface 4a of the chuck table 2 according to the first embodiment. In the experiment, the planarity of a face side 11a of the workpiece 11 held under suction on the holding surface 4a was measured using a dial gauge. Specifically, the relative heights (μm) of the center of the face side 11a of the workpiece 11 and four points on the outer circumferential portion of the face side 11a which are spaced at substantially equal intervals were measured using the dial gauge.

As illustrated in FIG. 3B, if it is assumed that the two points in the directions of 3 o'clock and 9 o'clock on the outer circumferential portion had a height of 0 μm (i.e., a reference height), the point in the direction of 12 o'clock on the outer circumferential portion had a height of −1 μm, and the point in the direction of 6 o'clock on the outer circumferential portion had a height of +2 μm. The central portion had a height of +1 μm. The difference between the heights of the central portion and the outer circumferential portion was a maximum of 2 μm.

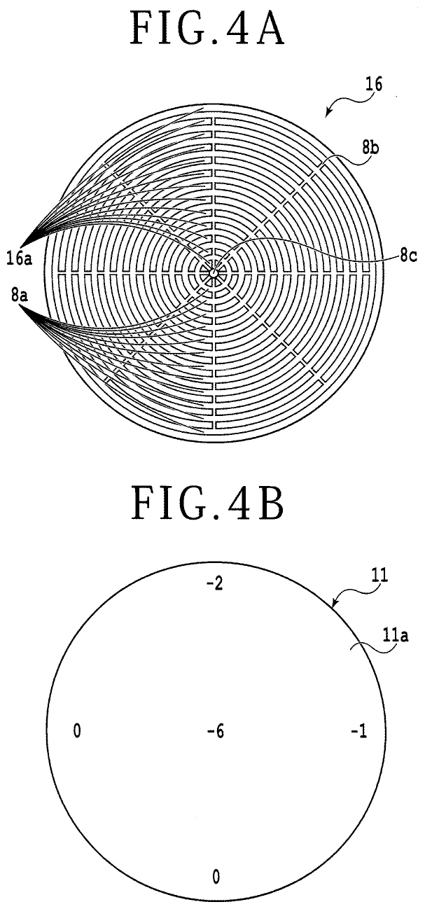

FIG. 4A illustrates in plan a base 16 of an undepicted chuck table according to a comparative example. FIG. 4B illustrates the results of an experiment conducted to measure deformations of the workpiece 11 held under suction on a holding surface of the chuck table according to the comparative example. The chuck table according to the comparative example includes the base 16 and the porous plate 4 placed on the base 16. In the experiment conducted in the comparative example, the magnitude of a negative pressure, i.e., a gauge pressure, applied from the suction source 14 to the base 16 was the same as the magnitude of the negative pressure applied in the experiment illustrated in FIGS. 3A and 3B.

The base 16 according to the comparative example is different from the base 6 according to the first embodiment in that the base 16 includes a plurality of annular suction channels 8a that are spaced at substantially equal intervals diametrically across an upper surface 16a thereof. In the experiment conducted in the comparative example, while a workpiece 11 that is the same as the workpiece 11 in the experiment conducted in the first embodiment was held under suction on the holding surface of the chuck table, the relative heights (μm) of the center of the face side 11a of the workpiece 11 and four points on the outer circumferential portion of the face side 11a which are spaced at substantially equal intervals were measured using the dial gauge.

As illustrated in FIG. 4B, if it is assumed that the two points in the directions of 6 o'clock and 9 o'clock on the outer circumferential portion had a height of 0 μm (i.e., a reference height), the point in the direction of 12 o'clock on the outer circumferential portion had a height of −2 μm, and the point in the direction of 3 o'clock on the outer circumferential portion had a height of −1 μm. The central portion had a height of −6 μm. The difference between the heights of the central portion and the outer circumferential portion was a maximum of 6 μm, indicating that the central portion was largely recessed. The experimental results illustrated in FIGS. 3B and 4B indicate that making the ratio of the area of the suction channels 8 to the area of the upper surface 6a smaller in the central portion 10a than in the outer circumferential portion 10b is effective to reduce the difference between suction forces applied to the radially central portion 10a and the radially outer circumferential portion 10b of the holding surface 4a.

### Second Embodiment

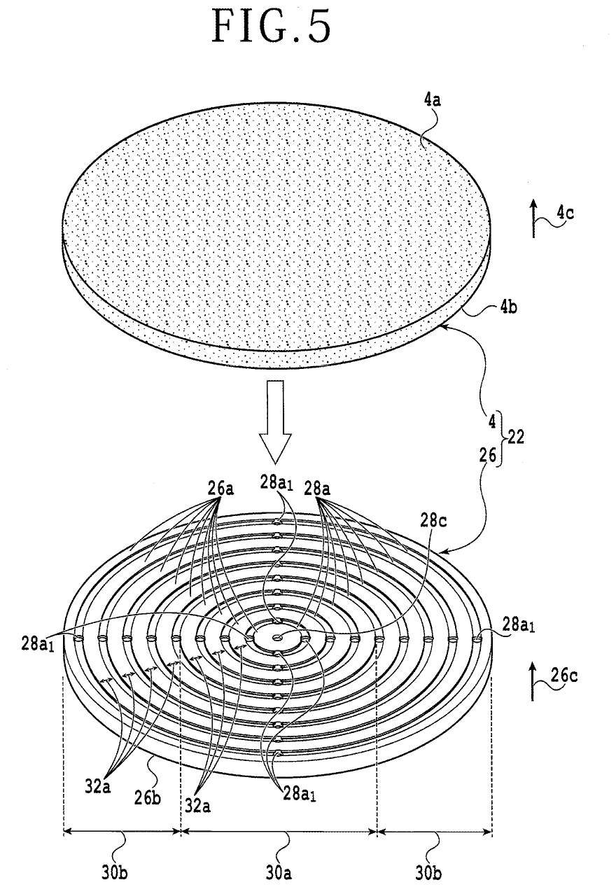

A second embodiment of the present invention will be described in detail below with reference to FIGS. 5 through 7C. FIG. 5 illustrates in exploded perspective a circular chuck table 22 according to the second embodiment. As illustrated in FIG. 5, the chuck table 22 has a circular porous plate 4. The porous plate 4 is the same as the porous plate 4 according to the first embodiment, and will be omitted from detailed description. The chuck table 22 further has a base 26 shaped as a circular plate on which the porous plate 4 is placed.

The base 26 has substantially the same diameter as that of the porous plate 4. The base 26 has an upper surface 26a that is a surface on an axial end of the base 26 along a thicknesswise direction 26c thereof. When the porous plate 4 is placed on the base 26, the upper surface 26a of the base 26 is held in contact with the lower surface 4b of the porous plate 4. The base 26 also has a lower surface 26b that lies opposite the upper surface 26a along the thicknesswise direction 26c of the base 26. The porous plate 4 according to the second embodiment is held under suction on the base 26 by a negative pressure transmitted to the porous plate 4. However, the porous plate 4 may alternatively be secured to the base 26 by an adhesive or bolts. The base 26 has a plurality of annular suction channels 28a defined in the upper surface 26a concentrically around a hollow cylindrical suction channel 28c, to be described later, defined centrally in the base 26. The annular suction channels 28a are exposed upwardly.

The annular suction channels 28a divide the upper surface 26a into a plurality of annular island-shaped regions. The annular suction channels 28a are spaced at substantially equal intervals 32a in a circular central portion 30a and an annular outer circumferential portion 30b of the upper surface 26a. The circular central portion 30a has a diameter of approximately 100 mm, for example, and the base 26 has a diameter of approximately 220 mm, for example. However, the diameter of the central portion 30a and the diameter of the base 26 are not limited to these numerical values.

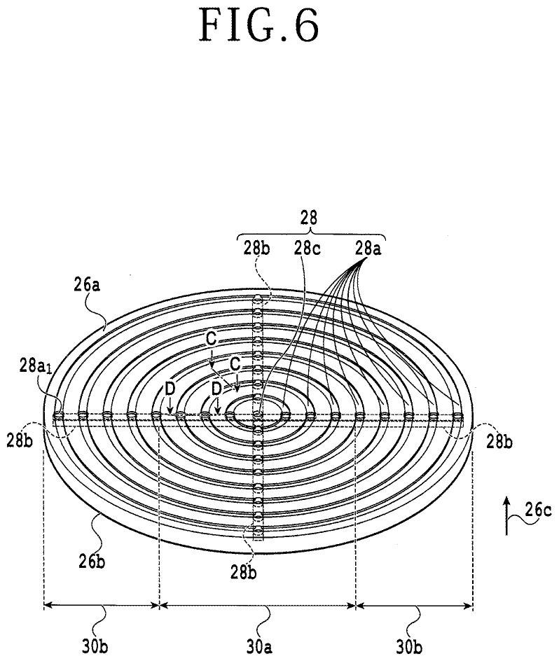

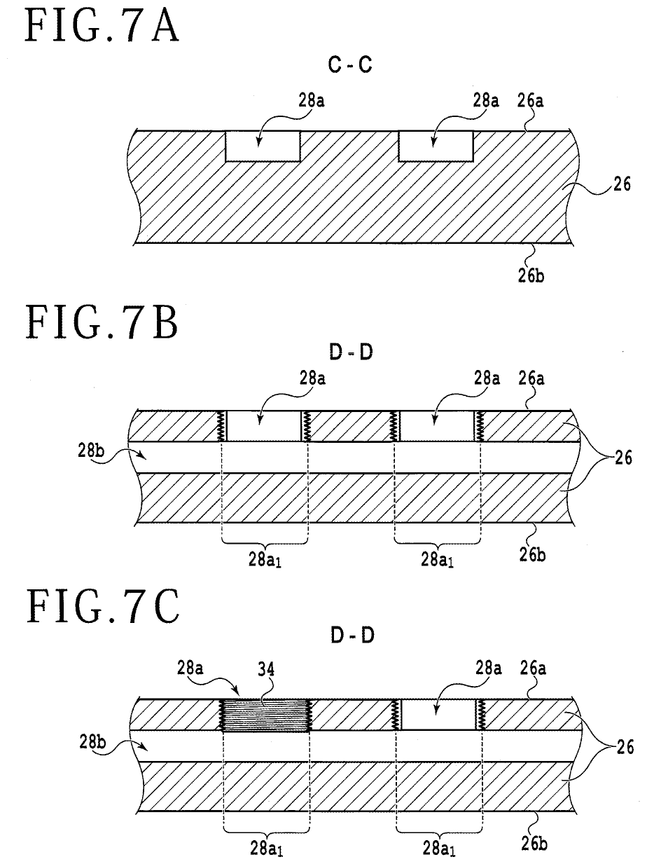

The annular suction channels 28a have respective bottoms each having a plurality of, i.e., four in the second embodiment, fluid communication channels 28a1 defined therein. Each of the fluid communication channels 28a1 is shaped as a cylindrical space whose diameter is substantially the same as the width of each of the annular suction channels 28a. In each of the annular suction channels 28a, the fluid communication channels 28a1 are spaced at substantially equal intervals in the circumferential directions of the base 26. The fluid communication channels 28a1 in the annular suction channels 28a are positioned on and along two diametrical lines extending perpendicularly to each other across the base 26. Therefore, when the base 26 is viewed in plan, the fluid communication channels 28a1 are disposed in a crisscross pattern. The annular suction channels 28a are fluidly connected to a plurality of lower suction channels 28b (see FIGS. 6, 7B, and 7C) defined in the base 26 beneath the annular suction channels 28a through the fluid communication channels 28a1 along the thicknesswise direction 26c of the base 26.

FIG. 6 illustrates in perspective the lower suction channels 28b defined in the base 26. In FIG. 6, the lower suction channels 28b are indicated by the broken lines. When the base 26 is viewed in plan, the lower suction channels 28b are disposed diametrically in a crisscross layout as described above. When the base 26 is viewed in plan, the lower suction channels 28b extend radially from the diametrical center of the base 26 to the annular suction channel 8a that is positioned in a radially outermost portion of the base 26. The hollow cylindrical suction channel 28c referred to above is defined diametrically centrally in the base 26.

The hollow cylindrical suction channel 28c extends axially through the base 26 from the upper surface 26a to the lower surface 26b along the thicknesswise direction 26c of the base 26. The hollow cylindrical suction channel 28c is fluidly connected to the lower suction channels 28b and is also fluidly connected to the suction source 14 via an undepicted fluid channel connected to the base 26. A negative pressure generated by the suction source 14 is transmitted through the fluid channel and the hollow cylindrical suction channel 28c to the lower suction channels 28b and then through the lower suction channels 28b to the annular suction channels 28a. The negative pressure generated by the suction source 14 is thus transmitted to the porous plate 4 via a plurality of suction channels 28 in the base 26 that are made up of the annular suction channels 28a, the lower suction channels 28b, and the hollow cylindrical suction channel 28c.

FIG. 7A, which is a cross-sectional view taken along line C-C of FIG. 6, illustrates in cross section the base 26 along a cross-sectional plane that does not pass through the fluid communication channels 28a1 and the lower suction channels 28b but passes through the annular suction channels 28a. FIG. 7B, which is a cross-sectional view taken along line D-D of FIG. 6, illustrates in cross section the base 26 along a cross-sectional plane that passes through the fluid communication channels 28a1, the lower suction channels 28b, and the annular suction channels 28a. The hollow cylindrical suction channel 28c and the fluid communication channels 28a1 are internally threaded channels, and, when necessary, are sealed by sealing members 34 (see FIG. 7C) such as a set screw (also known as a hexagonal socket head set screw), a screw and an externally threaded male screw.

FIG. 7C is a cross-sectional view taken along line D-D of FIG. 6, illustrating the manner in which one of the communication channels 28a1 is sealed by a sealing member 34. In FIG. 7C, the sealing member 34 is illustrated in side elevation. For example, all of the communication channels 28a1, i.e., the four communication channels 28a1 in the second embodiment, in the second annular suction channel 28a from the radially innermost annular suction channel 28a in the base 26 are sealed by respective sealing members 34. In this manner, the negative pressure from the suction source 14 is not transmitted to the second annular suction channel 28a from the radially innermost annular suction channel 28a in the base 26.

According to the second embodiment, each of the sealing members 34 is a set screw of metal, and hence has a bottomed hollow cylindrical shape having an externally threaded outer circumferential side surface. When a sealing member 34 is threaded into a communication channel 28a1, the communication channel 28a1 is sealed by the sealing member 34. At this time, the sealing member 34 is tightened in the communication channel 28a1 such that the sealing member 34 has an upper end not protruding upwardly from the upper surface 26a and a lower end not fully closing the lower suction channel 28b.

Since the sealing members 34 do not protrude upwardly from the upper surface 26a, even though the sealing members 34 are tightened in the communication channel 28a1, the porous plate 4 is supported and held under suction on the upper surface 26a. Further, since the sealing members 34 do not fully close the lower suction channel 28b, even though all of the communication channels 28a1 in the second annular suction channel 28a from the radially innermost annular suction channel 28a in the base 26 and the hollow cylindrical suction channel 28c are sealed by the respective sealing members 34, the negative pressure from the suction source 14 is transmitted to the annular suction channels 28a other than the second annular suction channel 28a from the radially innermost annular suction channel 28a. The sealing member 34 is tightened in the hollow cylindrical suction channel 28c such that the sealing member 34 does not protrude upwardly from the upper surface 26a and does not fully keep the lower suction channels 28b and the hollow cylindrical suction channel 28c out of fluid communication with each other.

According to the second embodiment, one or more of the annular suction channels 28a where all the fluid communication channels 28a1, i.e., four fluid communication channels 28a1 per annular suction channel 28a as illustrated in FIGS. 5 and 6, which are not sealed by the sealing members 34 and the hollow cylindrical suction channel 28c make up the suction channels 28 that are exposed on the upper surface 26a in such a manner as to be able to supply the negative pressure to the porous plate 4. Therefore, by sealing either at least all the fluid communication channels 28a1 in one or more of the annular suction channels 28a that are positioned in the central portion 30a of the upper surface 26a or the hollow cylindrical suction channel 28c with the sealing member or members 34 to stop supplying the negative pressure from the suction source 14, the area taken up by the suction chambers 28 that are exposed in such a manner as to be able to supply the negative pressure is adjusted.

By stopping the negative pressure from being supplied from the suction source 14 to one or more of the annular suction channels 28a and/or the hollow cylindrical suction channel 28c, when the base 26 is viewed in plan, the ratio of the area of the suction channels 28 that are exposed in such a manner as to be able to supply the negative pressure to the porous plate 4 to the sum of the area of the upper surface 26a and the area of the suction channels 28 that are exposed in such a manner as to be able to supply the negative pressure to the porous plate 4 can be made smaller in the central portion 30a than in the outer circumferential portion 30b.

More specifically, the ratio (S6/(S5+S6)) of the area (S6) of the suction channels 28 that are positioned in the central portion 30a and exposed in such a manner as to be able to supply the negative pressure to the porous plate 4 to the sum of the area (S5) of the upper surface 26a positioned in the central portion 30a and the area (S6) can be made smaller than the ratio (S8/(S7+S8)) of the area (S8) of the suction channels 28 that are positioned in the outer circumferential portion 30b and exposed in such a manner as to be able to supply the negative pressure to the porous plate 4 to the sum of the area (S7) of the upper surface 26a positioned in the outer circumferential portion 30b and the area (S8).

Therefore, when the porous plate 4 is placed on the base 26 and the workpiece 11 is held under suction on the holding surface 4a, the difference between suction forces applied to the radially central portion 30a and the radially outer circumferential portion 30b of the holding surface 4a is reduced. Further, the workpiece 11 that is held under suction on the holding surface 4a is prevented from being damaged due to deformations which would otherwise be caused by different suction forces applied to the holding surface 4a. According to the second embodiment, in addition, inasmuch as the fluid communication channels 28a1 can selectively be sealed by the sealing members 34 by way of the threaded structure, the fluid communication channels 28a1 can repeatedly be sealed and opened. Moreover, the second embodiment is advantageous in that, even after the annular suction channels 28a have been formed in the base 26, the number of suction channels 28 that are capable of supplying the negative pressure to the porous plate 4 can be adjusted.

FIG. 8 illustrates in perspective a laser processing apparatus (processing apparatus) 40 that incorporates the chuck table 2 or the chuck table 22. The details of the chuck table 2 are also applicable to the chuck table 22. In FIG. 8, an X-axis, a Y-axis, and a Z-axis represented respectively by arrows X, Y, and Z extend perpendicularly to each other. The X-axis extends substantially parallel to a processing feed direction. The Y-axis extends substantially parallel to an indexing feed direction. The Z-axis extends substantially parallel to a heightwise direction (vertical direction).

The laser processing apparatus 40 includes a base member 42 that supports various components thereof. The base member 42 includes a horizontal section 44 shaped as a flat plate and a wall section 46 that is positioned at a rear end of the horizontal section 44 and that extends upwardly. The chuck table 2 for holding the workpiece 11 under suction thereon is disposed over the horizontal section 44. A ball-screw-type Y-axis movable unit 48 for moving the chuck table 2 along the Y-axis is disposed on the horizontal section 44 beneath the chuck table 2. The Y-axis movable unit 48 includes a pair of Y-axis guide rails 50 that is fixedly mounted on an upper surface of the horizontal section 44 and that extends substantially parallel to the Y-axis.

A Y-axis movable table 52 is slidably mounted on the Y-axis guide rails 50. The Y-axis movable table 52 has a lower surface on which an undepicted nut is fixedly mounted. The nut is operatively threaded over a screw shaft 54 with a plurality of undepicted balls interposed therebetween. The screw shaft 54 extends substantially parallel to the Y-axis between the guide rails 50. The screw shaft 54 has an end coupled to a drive source 56 such as a stepping motor, for example. When the drive source 56 is energized, it rotates the screw shaft 54 about its central axis, causing the nut to move the Y-axis movable table 52 on the guide rails 50 along the Y-axis. The Y-axis movable table 52 supports on its upper surface a ball-screw-type X-axis movable unit 58 for moving the chuck table 2 along the X-axis.

The X-axis movable unit 58 includes a pair of X-axis guide rails 60 that is fixedly mounted on an upper surface of the Y-axis movable table 52 and that extends substantially parallel to the X-axis. An X-axis movable table 62 is slidably mounted on the X-axis guide rails 60. The X-axis movable table 62 has a lower surface on which an undepicted nut is fixedly mounted. The nut is operatively threaded over a screw shaft 64 with a plurality of undepicted balls interposed therebetween. The screw shaft 64 extends substantially parallel to the X-axis between the guide rails 60. The screw shaft 64 has an end coupled to a drive source 66 such as a stepping motor, for example. When the drive source 66 is energized, it rotates the screw shaft 64 about its central axis, causing the nut to move the X-axis movable table 62 on the guide rails 50 along the X-axis.

A cylindrical support base 68 is mounted on an upper surface of the X-axis movable table 62. The chuck table 2 is disposed on the upper end of the support base 68. The support base 68 houses therein an undepicted drive source such as an electric motor for turning the chuck table 2 through a predetermined angle about a vertical rotational axis parallel to the Z-axis when necessary. The workpiece 11 held under suction on the holding surface 4a of the chuck table 2 has a monocrystalline silicon substrate shaped as a circular plate, for example.

A grid of projected dicing lines (streets) are established on the face side 11a of the workpiece 11. The projected dicing lines demarcate a plurality of rectangular areas on the face side 11a where respective devices such as integrated circuits (ICs) are constructed. The devices are not limited to particular types, quantities, shapes, structures, sizes, and layouts, for example. The workpiece 11 may be free of devices. Although not illustrated in FIG. 8, the workpiece 11 may be formed as a workpiece unit where the workpiece 11 is supported by an annular frame of metal through a dicing tape of resin. In that case, the workpiece is held under suction on the chuck table 2 through the dicing tape.

A support arm 70 extends forwardly from an upper portion of a front surface of the wall section 46. The support arm 70 supports a laser beam applying unit 72 that includes a cylindrical head 74 in its front end portion. The laser beam applying unit 72 has an undepicted laser oscillator fixedly positioned with respect to the base member 42. The laser oscillator has a crystal of Nd: YAG, for example, as a laser medium. The head 74 emits an undepicted pulsed laser beam having a predetermined wavelength of 355 nm or 1064 nm, for example.

A microscope camera unit 76 is mounted on its distal end of the support arm 70 adjacent to the laser beam applying unit 72. The microscope camera unit 76 has a cylindrical head 78 that is located adjacent to the head 74 of the laser beam applying unit 72. The microscope camera unit 76 includes an objective lens, a focusing lens, a light source, and a solid-state image sensor, all of which are not depicted, for example.

An undepicted outer cover is mounted on the base member 42 in covering relation to the components described above of the laser processing apparatus 40. A touch panel 80 is attached to a front wall of the outer cover which is remote from the wall section 46 along the Y-axis. The touch panel 80 functions as an input device that can be used by an operator to enter instructions to the laser processing apparatus 40 and a display device for displaying images captured by the microscope camera unit 76 and other information.

The laser processing apparatus 40 has a controller (control unit) 82 for controlling the Y-axis movable unit 48, the X-axis movable unit 58, the drive source housed in the support base 68, the suction source 14, which is not depicted in FIG. 8, included in the laser processing apparatus 40, the laser beam applying unit 72, the microscope camera unit 76, and the touch panel 80, for example. The controller 82 has a computer including a processor (processing device), typically a central processing unit (CPU), a main storage device such as a dynamic random access memory (DRAM), a static random access memory (SRAM), or a read only memory (ROM), and an auxiliary storage device such as a flash memory, a hard disk drive, or a solid-state drive. The auxiliary storage device stores software including predetermined programs. The processor and other components of the controller 82 are operated according to the software to perform the functions of the controller 82.

The chuck table 2 or 22 may be applied to other processing apparatuses such as a cutting apparatus, a polishing apparatus, and a grinding apparatus, instead of the laser processing apparatus 40. The structural and operational details of the embodiments described above may be changed or modified without departing from the scope of the present invention. For example, an annular region positioned on an outermost circumferential portion of the upper surface 6a of the base 6 may be raised to protrude upwardly, thereby providing a circular cavity in the upper surface 6a, and a porous plate 4 having substantially the same diameter as that of the cavity may be fitted in the cavity. The porous plate 4 thus fitted in the cavity may be fixed to the base 6 by an adhesive. However, the porous plate 4 may be fixed to the base 6 by bolts. This cavity and fixing process is also applicable to the base 26 and the porous plate 4 combined therewith.

In a case where a circular cavity is provided in the upper surface 6a, if both the porous plate 4 and the base 6 are made of glass, then the porous plate 4 and the base 6 may be brought into intimate contact with each other and fixed to each other by softening and deforming the base 6 with heat, instead of using an adhesive or bolts. This fixing process is also applicable to the base 26 and the porous plate 4 combined therewith.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A chuck table for holding a workpiece under suction thereon, the chuck table comprising:
a plate-shaped porous plate having a holding surface for holding the workpiece under suction thereon; and
a plate-shaped base having an upper surface on which the porous plate is placed, the upper surface being held in contact with a lower surface of the porous plate, the lower surface being positioned opposite the holding surface, wherein
the base has a plurality of suction channels defined therein that are exposed on the upper surface of the base and that are for transmitting a negative pressure from a suction source to the porous plate, and,
when the base is viewed in plan, the base is configurable so that a ratio of an area of the suction channels that are exposed in such a manner as to be able to supply a negative pressure to the porous plate to a sum of an area of the upper surface of the base and the area of the suction channels that are exposed in such a manner as to be able to supply the negative pressure to the porous plate is smaller in a central portion of the upper surface of the base than in an outer circumferential portion of the upper surface of the base.

2. The chuck table according to claim 1, wherein,
when the base is viewed in plan, a ratio of an area of the suction channels to a sum of the area of the upper surface of the base and the area of the suction channels is smaller in the central portion of the upper surface of the base than in the outer circumferential portion of the upper surface of the base.

3. The chuck table according to claim 1, wherein
the suction channels that are exposed in such a manner as to be able to supply the negative pressure to the porous plate include a hollow cylindrical suction channel that is defined diametrically centrally in the base and that extends axially through the base from the upper surface thereof to a lower surface of the base along a thicknesswise direction of the base, and a plurality of annular suction channels defined in the base concentrically around the hollow cylindrical suction channel,
the base further includes a plurality of lower suction channels that are defined therein beneath the annular suction channels and that extend radially in the base when the base is viewed in plan, with the negative pressure being transmittable from the suction source through the hollow cylindrical suction channel to the lower suction channels,
each of the annular suction channels includes a plurality of fluid communication channels fluidly connected to the lower suction channels along the thicknesswise direction of the base, and
at least either all the fluid communication channels in each of one or more of the annular suction channels that are positioned in the central portion of the upper surface of the base or the hollow cylindrical suction channel is sealed, and when the base is viewed in plan, the ratio of the area of the suction channels that are exposed in such a manner as to be able to supply the negative pressure to the porous plate to the sum of the area of the upper surface of the base and the area of the suction channels that are exposed in such a manner as to be able to supply the negative pressure to the porous plate is smaller in the central portion of the upper surface of the base than in the outer circumferential portion of the upper surface of the base.
